(19) United States
(12) Patent Application Publication
(10) Pub. No.: US 2014/0041838 A1
(43) Pub. Date: Feb. 13, 2014

(54) HEAT PIPE ASSEMBLY AND HEAT DISSIPATION DEVICE HAVING THE SAME

(71) Applicants: Golden Sun News Techniques Co., Ltd, New Taipei City (TW); Cpumate Inc., New Taipei City (TW)

(72) Inventors: Kuo-Len LIN, New Taipei City (TW); Chen-Hsiang LIN, New Taipei City (TW); Chih-Hung CHENG, New Taipei City (TW)

(73) Assignees: Golden Sun News Techniques Co., Ltd, New Taipei City (TW); Cpumate Inc., New Taipei City (TW)

(21) Appl. No.: 14/056,802

(22) Filed: Oct. 17, 2013

Related U.S. Application Data
(63) Continuation-in-part of application No. 12/554,865, filed on Sep. 4, 2009.

(51) Int. Cl. H05K 7/20

(52) U.S. Cl. CPC H05K 7/20336
USPC 165/104.21

(57) ABSTRACT

A heat pipe assembly includes a number of heat pipes and a fixing seat. Each of the heat pipes includes an evaporating section and at least a condensing section. A bottom of the evaporating section of each of the heat pipes is flat and has a flat heat absorbing surface. The evaporating sections of each of the heat pipes are parallel to and adjoin with each other, whereby the flat heat absorbing surfaces of the evaporating sections of the heat pipes being coplanar and adjoining with each other. A top surface of the evaporating section of each of the heat pipes has a top edge. The fixing seat, as a molded one-piece member, combines with the top edge of the evaporating section of each of the heat pipes, whereby the heat absorbing surfaces of the evaporating sections of the heat pipes are coplanar and adjoin with each other.

### CROSS-REFERENCE

This application is a continuation-in-part application of U.S. patent application Ser. No. 12/554,865, filed Sep. 4, 2009.

### BACKGROUND

The present invention relates to heat dissipation devices, and particularly to a heat pipe assembly including a number of heat pipes and a fixing structure which enables evaporating sections of the heat pipes being parallel to and adjoining with each other, and a heat dissipation device including such a heat pipe assembly.

With the development of computer technologies, electronic elements run at high speed and therefore generate large amounts of heat. In order to keep the electronic elements operating at a normal temperature, the heat must be quickly and efficiently removed from the electronic elements by a heat dissipation device. Conventionally, the heat dissipation device includes a heat pipe which uses a gas-liquid phase transition technology to dissipate the heat generated by the electronic elements.

However, in order to increase the heat dissipation efficiency of the heat dissipation device, a number of heat pipes are included in the heat dissipation device. Currently, the heat pipes are secured to a base seat or a heat conducting seat of the heat dissipation device by welding method. Also, evaporation sections of the heat pipes may be embedded in the grooves defined on the base seat or the heat conducting seat of the heat dissipation device and secured to the base seat or the heat conducting seat. However, the welding process is not easy to perform and the welded heat dissipation device has an unattractive appearance. When the evaporation sections of the heat pipes are embedded in the groves of the base seat or a heat conducting seat, the evaporation sections must be spaced from each other and can not be tightly adjoin with each other, whereby the evaporating sections can not be gathered to thermally contact with a surface of a heat generating electronic element. As a result, outermost two of the heat pipes can not be sufficiently used, thereby the heat dissipation device having low heat dissipation efficiency.

Therefore, what is needed is a heat pipe assembly and a heat dissipation device including such a heat pipe assembly, thereby overcoming the above-described problems.

### BRIEF SUMMARY

The present invention provides a heat pipe assembly and a heat dissipation device including the heat pipe assembly. The heat pipe assembly includes a number of evaporation sections and a molded fixing seat. By the fixing structure, the evaporating sections of the heat pipe assembly are parallel to and adjoin with each other, whereby heat absorb surfaces of the evaporating sections are coplanar and adjoin with each other to thereby form a large-area heat absorbing surface to thermally contact with a heat generating electronic element.

The heat pipe assembly includes a number of heat pipes and a fixing seat engaging with evaporating sections of the heat pipes. Each of the heat pipes includes an evaporating section and at least a condensing section. A bottom of the evaporation section of each of the heat pipes is flat and has a flat heat absorbing surface. The evaporating sections of the heat pipes are parallel to and adjoin with each other, whereby the heat absorbing surfaces thereof are coplanar and adjoin with each other. A top surface of the evaporating section of each of the heat pipes has a top edge. The fixing seat has an integral structure and combines with the top edges of the evaporating sections of the heat pipes, thereby facilitating the heat absorbing surfaces of the evaporating sections of the heat pipes being coplanar and adjoining with each other.

A heat dissipation device including above-described heat pipe assembly is provided. The heat dissipation device further comprises a number of heat conducting fins disposed on the condensing sections of the heat pipes.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic, isometric view of a heat pipe assembly, according to a first embodiment of the present disclosure.

FIG. 2 is a schematic, isometric view of the heat pipe assembly from a visual angle different from FIG. 1.

FIG. 3 is a partially, cross-sectional view of FIG. 1.

FIG. 4 is a partially, cross-sectional view of FIG. 2.

FIG. 5 is a partially, cross-sectional view of a heat pipe assembly, according to a second embodiment of the present disclosure.

FIG. 6 is a partially, exploded view of a heat dissipation device of the present disclosure.

### DETAILED DESCRIPTION

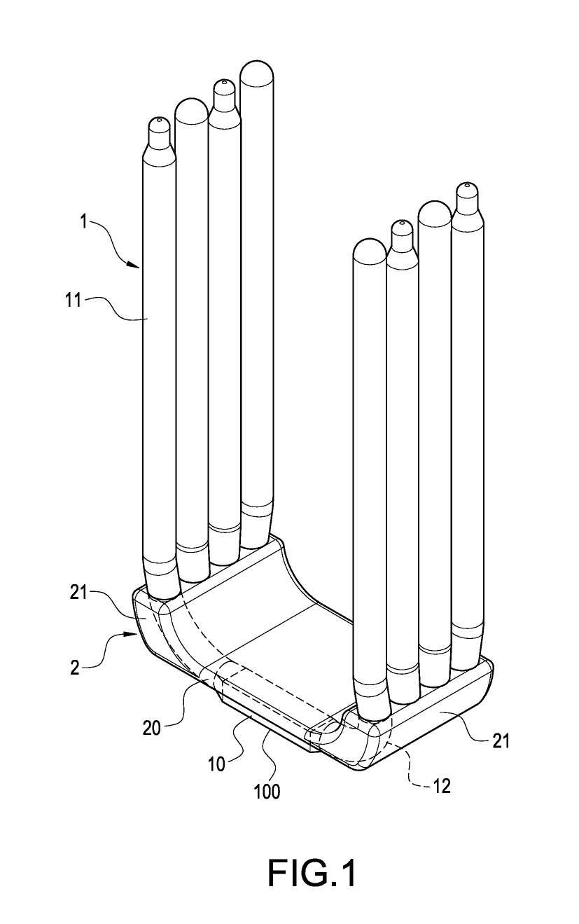

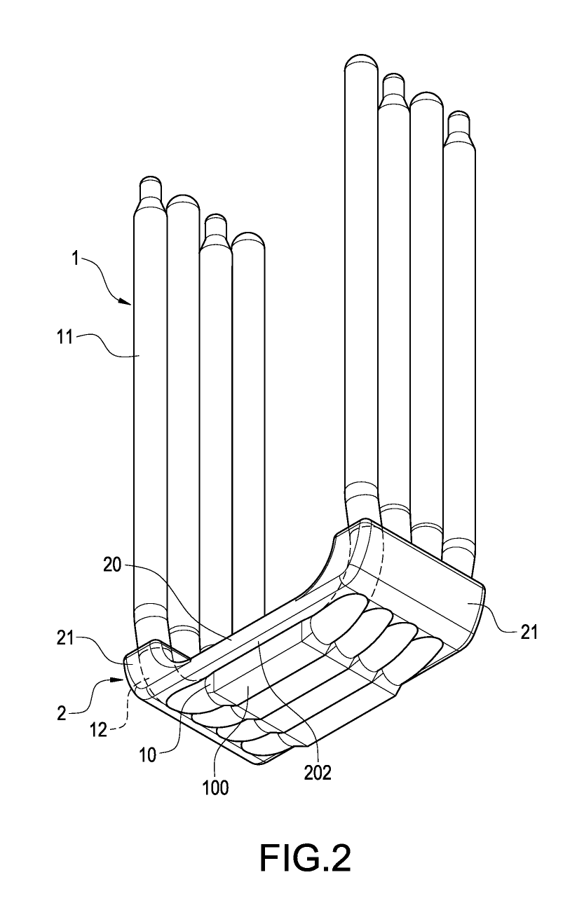

FIGS. 1 and 2 are schematic, isometric views of a heat pipe assembly of the present invention in different visual angles. The heat pipe assembly includes a number of heat pipes 1 and a fixing seat 2.

Each of the heat pipes 1 is a heat conducting element and includes a vacuous tubular body, a capillary structure disposed inside the tubular body and a working fluid contained in the tubular body and soaking the capillary structure. The tubular body of each of the heat pipes 1 is an integral structure and has a certain length. The heat pipes 1 each include an evaporating section 10 and at least a condensing section 11 connected with the evaporating section 10. In the present embodiment, each of the heat pipes 1 has a U-shaped configuration, a bottom portion of the U-shaped configuration is the evaporating section 10, and two lateral portions of the U-shaped configuration are two condensing sections 11. A curved section 12 is connected between the evaporation section 10 and each condensing section 11. Thus, the evaporation section 10, two condensing sections 11 and two curved sections 12 cooperatively form each of the heat pipes 1. In addition, a bottom of the evaporation section 10 of each of the heat pipes 1 is flat and has a flat heat absorbing surface 100. Evaporating sections 10 of the heat pipes 1 are parallel to and adjoin with each other, whereby the heat absorb surfaces 100 of the evaporating sections 10 are coplanar and adjoin with each other to thereby form a large-area heat absorbing surface.

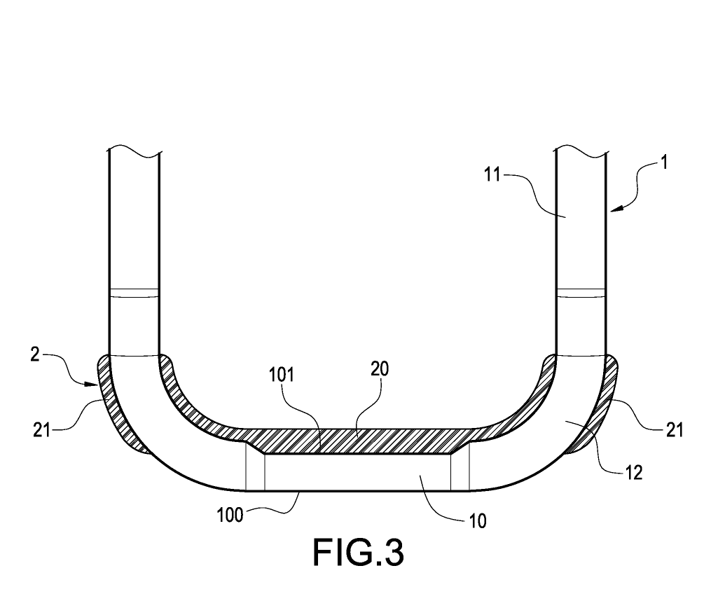

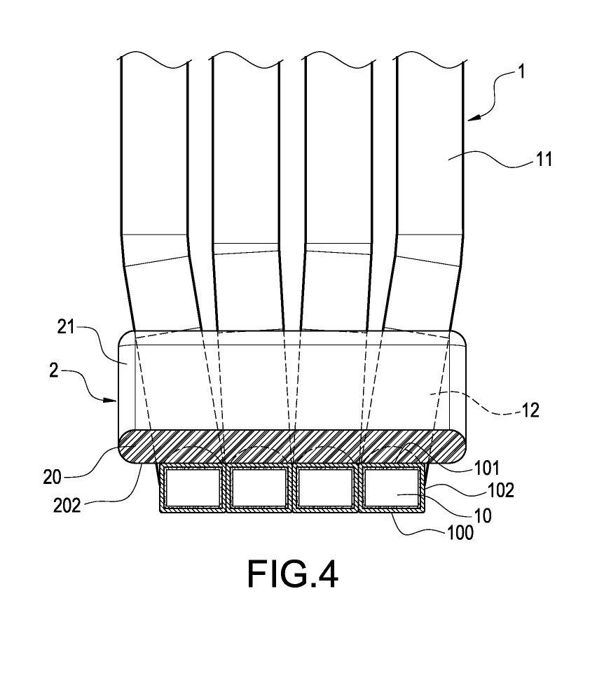

Together referring to FIGS. 3 and 4, the fixing seat 2 has an integral configuration and is made of plastic materials, such as, PC, PP, PE, PU or the like. The fixing seat 2 is made by integral molding process, e.g., injection molding, gel-casting molding, perfusion molding, die casting, dipping and so on. The fixing seat 2, as a molded one-piece plastic member, engages with the evaporating sections 10 of the heat pipes 1. The fixing seat 3 has a base 20, a top surface the evaporation section 10 of each of the heat pipes 1 has a top edge 101. A bottom surface of the base 20 defines an engaging edge 202 being flush with the top edge 101 of the top surface of the evaporation section 10 of each of the heat pipes 1, whereby the evaporation sections 10 of the heat pipes 1 can be secured to enable the heat absorbing surfaces 100 of the evaporation sections 10 of the heat pipes 1 being parallel to and adjoining with each other. As a result, the heat absorbing surfaces 100 are coplanar and adjoin with each other to form a large-area surface, thereby facilitating thermally contacting with heat-generating sources (not shown). In addition, in order to increase a contact area between the fixing seat 2 and the heat pipes 1, the fixing seat 2 further includes two reinforcement portions 21 respectively extending outwardly from two lateral ends of the base 20. The reinforcement portion 21 located at right side of the base 20 of the fixing seat 2 encloses all of the curved sections 12 of the heat pipes 1 located at right side of the base 20 of the fixing seat 2; the reinforcement portion 21 located at left side of the base 20 of the fixing seat 2 encloses all of the curved sections 12 of the heat pipes 1 located at left side of the base 20 of the fixing seat 2; thereby enhancing a bonding strength between the fixing seat 2 and the heat pipes 1.

In order to ensure the evaporation sections 10 of the heat pipes 1 being parallel to and adjoining with each other, a cross section of each of the evaporation sections 10 is square or rectangular, as shown in FIG. 4. Thus, each of the evaporation sections 10 has two vertical lateral walls 102, and the lateral walls 102 of adjacent evaporation sections 10 tightly joint with each other. As a result, the evaporation sections 10 of the heat pipes 1 can be gathered together to facilitate the evaporation sections 10 of the heat pipes 1 exchanging heat, whereby the heat pipes 1 can be evenly heated. Furthermore, as shown in FIG. 4, the curved sections 12 of the heat pipes 1 are radially arranged relative to an assembly of the evaporation sections 10 of the heat pipes, that is, adjacent curved sections 12 are angled with each other, whereby the condensing sections 11 of the heat pipes 1 are spaced from each other. In the illustrated embodiment, the condensing sections 11 of the heat pipes 1 are vertical to the evaporating sections 10 of the heat pipes 1.

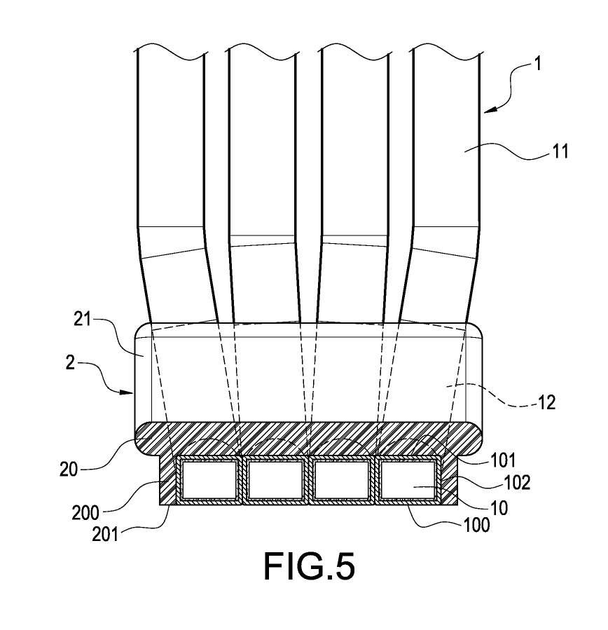

Referring to FIG. 5, the fixing seat 2 includes two enclosing portions 200 extending downwardly from the engaging edge 202 of the base 20 to respectively enclose the lateral walls 102 of the two outermost heat pipes 1, thereby enhancing the bonding strength among the evaporating sections 10 of the heat pipes 1. The enclosing portions 200 each include a bottom edge 201 not protrude downwardly relative to the heat absorbing surfaces 100. In the present embodiment, the bottom edges 201 of the enclosing portions 200 are coplanar with the heat absorbing surfaces 100.

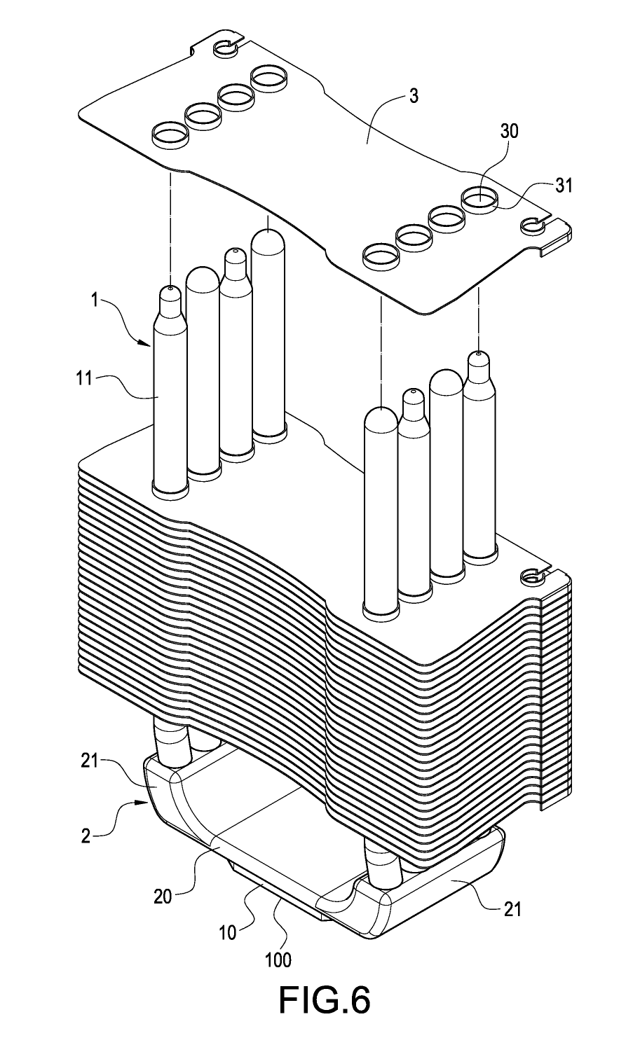

Referring to FIG. 6, a heat sink having the above-described heat pipe assembly of FIG. 1 is illustrated. The heat sink includes a number of heat conducting fins 3. The heat conducting fins 3 are parallel to and equidistantly spaced from each other. Two lateral portions of each of the heat conducting fins 3 defines a number of through holes 30 to allow the condensing sections 11 of the heat pipes 1 passing therethrough. An annular protruded flange 31 extends upwardly from an circumference edge defining each of the through holes 30 to enable adjacent heat conducting fins 3 spaces a certain distance. Thus, the heat conducting fins 3 define a number of airflow passages to increase heat dissipation efficiency. In assembly, the condensing sections 11 of the heat pipes 1 respectively extend the through holes 30 of the heat conducting fins 3 to enable an assembly of the heat conducting fins 3 locating over the evaporation sections 10 of the heat pipes 1.

Therefore, the heat pipes 1 and the fixing seat 2 cooperatively constitute the heat pipe assembly; the heat pipe assembly and the heat conducting fins 3 are construct the heat sink.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A heat pipe assembly, comprising:
a plurality of heat pipes, each having an evaporating section, a condensing section, and a curved section connected between the evaporating section and the condensing section, a bottom of the evaporating section of each of the heat pipes being flat and having a flat heat absorbing surface, evaporating sections of the heat pipes being parallel to and adjoining to contact with each other, whereby flat heat absorbing surfaces of the evaporating sections of the heat pipes being coplanar and adjoining with each other, a top surface of the evaporating section of each of the heat pipes having a top edge; and
a molded one-piece plastic fixing seat formed on the top edge of the evaporating section of each of the heat pipes to combine with the curved section so that the evaporating sections are exposed out from the fixing seat, wherein the fixing seat comprises a base and a reinforcement portion extending outwardly from one end of the base to enclose curved sections of the heat pipes, a bottom surface of the base defines an engaging edge being flush with the top edge of the evaporating section of each of the heat pipes, and the reinforcement portion is extended continuously from the bottom surface of the base to have an inner surface of the reinforcement portion entirely contacted on the curved sections so that the heat pipes are securely held together.

2. The heat pipe assembly as claimed in claim 1, wherein each of the heat pipes has a U-shaped configuration, a bottom portion of the U-shaped configuration is the evaporating section, and two lateral portions of the U-shaped configuration are condensing sections.

3. The heat pipe assembly as claimed in claim 1, wherein the curved sections of the heat pipes are radially arranged and angled with each other, whereby the condensing sections of the heat pipes are spaced from each other.

4. The heat pipe assembly as claimed in claim 1, wherein the fixing seat further comprises an enclosing portion downwardly from the engaging edge of the base to respectively enclose lateral walls of two outermost heat pipes.

5. The heat pipe assembly as claimed in claim 4, wherein the enclosing portion of the fixing seat has a bottom edge coplanar with the heat absorbing surfaces of the evaporating sections of the heat pipes.

6. A heat dissipation device, comprising:
a plurality of heat pipes, each having an evaporating section, a condensing section, and a curved section connected between the evaporating section and the condensing section, a bottom of the evaporating section of each of the heat pipes being flat and having a flat heat absorbing surface, evaporating sections of the heat pipes being parallel to and adjoining to contact with each other, whereby flat heat absorbing surfaces of the evaporating sections of the heat pipes being coplanar and adjoining with each other, a top surface of the evaporating section of each of the heat pipes having a top edge;
a plurality of heat conducting fins disposed on the condensing sections of the heat pipes; and
a molded one-piece plastic fixing seat formed on the top edge of the evaporating section of each of the heat pipes to combine with the curved section so that the evaporating sections are exposed out from the fixing seat, wherein the fixing seat comprises a base and a reinforcement portion extending outwardly from one end of the base to enclose curved sections of the heat pipes, a bottom surface of the base defines an engaging edge being flush with the top edge of the evaporating section of each of the heat pipes, and the reinforcement portion is extended continuously from the bottom surface of the base to have an inner surface of the reinforcement portion entirely contacted on the curved sections so that the heat pipes are securely held together.

7. The heat dissipation device as claimed in claim 6, wherein each of the heat pipes has a U-shaped configuration, a bottom portion of the U-shaped configuration is the evaporating section, and two lateral portions of the U-shaped configuration are condensing sections.

8. The heat dissipation device as claimed in claim 6, wherein the curved sections of the heat pipes are radially arranged and angled with each other, whereby the condensing sections of the heat pipes are spaced from each other.

9. The heat dissipation device as claimed in claim 6, wherein the fixing seat further comprises an enclosing portion downwardly from the engaging edge of the base to respectively enclose lateral walls of two outermost heat pipes.

10. The heat dissipation device as claimed in claim 9, wherein the enclosing portion of the fixing seat has a bottom edge coplanar with the heat absorbing surfaces of the evaporating sections of the heat pipes.

11. The heat dissipation device as claimed in claim 6, wherein each of the heat conducting fins defines a through hole to allow the condensing section of each of the heat pipes pass through the through hole.

12. The heat dissipation device as claimed in claim 11, wherein an annular flange extends upwardly from a circumference edge defining the through hole of each of the heat conducting fins.
